(19) United States
(12) Patent Application Publication
(10) Pub. No.: US 2008/0298028 A1
(43) Pub. Date: Dec. 4, 2008

(54) AMC CARRIER FACEPLATES

(76) Inventor: Matthew Travers, Mansfield, MA (US)

Correspondence Address: STRATEGIC PATENTS P.C.., C/O PORTFOLIOIP, P.O. BOX 52050, MINNEAPOLIS, MN, 55402, US

(21) Appl. No.: 12/131,360

(22) Filed: Jun. 2, 2008

Related U.S. Application Data
(60) Provisional application No. 60/941,237, filed on May 31, 2007.

(51) Int. Cl. H05K 1/00

(52) U.S. Cl. 361/748

(57) ABSTRACT

A faceplate for AMC carriers is fabricated from extruded aluminum using a combination of extruded cross-sectional features and machined features to achieve the structural and functional characteristics of an AdvancedTCA faceplate. The extruded aluminum faceplate significantly improves on sheet-metal alternatives while substantially conforming to the AdvancedTCA specification.

### CROSS-REFERENCE TO RELATED APPLICATIONS

This application claims the benefit of U.S. App. No. 60/941,237 filed on May 31, 2007, the entire content of which is incorporated herein by reference.

### BACKGROUND

Enclosures are commonly used to house electronic components, devices, cards, and the like for use in larger electronic systems. The Peripheral Component Interconnect (“PCI”) Industry Manufacturing Group (“PICMG”) has ratified the PICMG 3.0 specification, also referred to as AdvancedTCA, along with a number of sub-specifications in order to standardize enclosures for applications such as high-performance telecommunications and industrial computing. Further standardization is provided by Advanced Mezzanine Card (“AMC”) specifications, a family of printed circuit board specifications targeted to requirements for the next generation of carrier grade telecommunications equipment. The AMC specifications define standards for hot-swappable, field-replaceable mezzanine cards intended for use with AdvancedTCA (“ATCA”) card carriers. Among other things, the PICMG 3.0 specification defines a faceplate for the front of these ATCA-compliant, AMC card carriers.

Faceplate standardization permits vendors to independently design and manufacture conforming parts. The AdvancedTCA faceplate specifications have been specifically developed with an eye toward sheet metal in order to support low-cost, high-volume manufacturing. The specification recommends a consistent one millimeter thickness in order to maintain a uniform look and feel among manufacturers, and explicitly discourages use of any internal surfaces extending beyond a “front board attachment plane” that extends another one millimeter into the carrier interior. Thus, while AdvancedTCA does not strictly require use of sheet metal, to date the commercially-available alternatives employ some form of shaped and/or stamped sheet metal. This may be due to the relative simplicity and low cost of sheet metal fabrication. However, another significant contributor is the tight physical constraints placed on the faceplate form factor by the AdvancedTCA specification.

While incremental uses of extruded material have been proposed, such as corner extrusions for an ATCA chassis, there remains a need for alternative techniques to fabricate AMC carrier faceplates for use in AdvancedTCA enclosures.

### SUMMARY

A faceplate for AMC carriers is fabricated from extruded aluminum using a combination of extruded cross-sectional features and machined features to achieve the structural and functional characteristics of an AdvancedTCA faceplate. The extruded aluminum faceplate significantly improves on sheet-metal alternatives while substantially conforming to the AdvancedTCA specification.

In one aspect, an extruded faceplate described herein includes an extruded material having a length sized for use as a faceplate for an AMC carrier, the extruded material having a front side that forms an outside surface of the AMC carrier and a rear side that forms an interior surface of the AMC carrier; the extruded material having a cross-sectional shape including a channel on the front side, the channel including a depressed, substantially planar surface sized for an adhesive overlay and the channel including two raised edges that confine the adhesive overlay to the channel; and the extruded material having at least one machined feature adapted for assembly into the AMC carrier.

The channel may have a depth substantially equal to a thickness of the adhesive overlay. The extruded faceplate may include at least one through-hole from the planar surface of the channel to the rear side of the extruded faceplate, the at least one through-hole shaped and sized for a light emitting diode. The extruded faceplate may include at least one through-hole from the planar surface of the channel to the rear side of the extruded faceplate, the at least one through-hole shaped and sized for at least one of a button, a switch, and a dial. The extruded faceplate may include an opening from the front side to the rear side, the opening shaped and sized to receive an ejector. The faceplate may include the adhesive overlay adhered to the channel.

In another aspect, there is disclosed herein an extruded material having a length sized for use as a faceplate for an AMC carrier, the extruded material having a front side that forms an outside surface of the AMC carrier and a rear side that forms an interior surface of the AMC carrier; the extruded material having a cross-sectional shape including a channel between the front side and the rear side, the channel including a depressed, substantially planar surface sized for an adhesive strip of EMI shield material; and the extruded material having at least one machined feature adapted for assembly into the AMC carrier.

The channel may be positioned to support the adhesive strip in a location where the AMC carrier physically mates with a chassis. The channel may be positioned to support the adhesive strip in a location where the AMC carrier physically mates with another faceplate. The channel may be substantially perpendicular to the front side and the rear side. The channel may include two raised edges that confine the adhesive strip to the channel. The extruded faceplate may include the adhesive strip of EMI shield material adhered to the channel.

In another aspect, an extruded faceplate disclosed herein includes an extruded material having a length sized for use as a faceplate for an AMC carrier, the extruded material having a front side that forms an outside surface of the AMC carrier and a rear side that forms an interior surface of the AMC carrier; the extruded material having a cross-sectional shape including a tapered edge extending rearward from and substantially perpendicular to the rear surface; and the extruded material having at least one machined feature adapted for assembly into the AMC carrier.

The tapered edge may include at least one tapered side to facilitate insertion of the AMC carrier into a chassis. The tapered edge may include a taper to facilitate attachment to a plurality of offset fingers extending from a sheet metal carrier cover. The extruded faceplate may include the sheet metal carrier cover, the sheet metal carrier cover attached to the extruded faceplate with at least two of the offset fingers on each side of the tapered edge.

In another aspect, an extruded faceplate as disclosed herein includes an extruded material having a length sized for use as a faceplate for an AMC carrier, the extruded material having a front side that forms an outside surface of the AMC carrier and a rear side that forms an interior surface of the AMC carrier; the extruded material having a cross-sectional shape including at least one profile feature adapted for assembly into the AMC carrier; and the extruded material having an opening machined therein extending from the front surface to the rear surface, the opening shaped and sized to receive an AMC module and the opening including a beveled edge oriented to guide insertion of the AMC module into the opening through the front surface.

The extruded faceplate may include at least one notch formed in an edge extending rearward from the rear surface, the notch providing two opposing lateral supports for a card guide positioned behind the extruded faceplate. The extruded faceplate may include an attachment leg extruded into the cross-sectional shape and extending rearward from the rear surface, the attachment leg adapted to secure a card guide strut in a position to support a carrier cover.

In another aspect, a card carrier disclosed herein includes a faceplate formed of an extruded material having a length sized for use in an AMC carrier, the faceplate having a front side that forms an outside surface of the AMC carrier and a rear side that forms an interior surface of the AMC carrier, the front side and the rear side connected by a top edge and a bottom edge to form a cross-sectional shape including at least one profile feature adapted for assembly into the AMC carrier, the extruded material further including at least one machined feature adapted for assembly into the AMC carrier, the faceplate forming a front of the card carrier; a first carrier cover formed of sheet metal and removably and replaceably attached to the top edge of the faceplate, the first carrier cover forming a top of the card carrier; a second carrier cover formed of sheet metal and removably and replaceably attached to the bottom edge of the faceplate, the second carrier cover forming a bottom of the card carrier; and a plurality of card guides interconnecting the first carrier cover and the faceplate, wherein adjacent ones of the plurality of card guides provide a pair of aligned rails for receiving and supporting one or more AMC cards.

The card carrier may include at least one card connecter including an edge connecter aligned with the pair of aligned rails and adapted to physically and electronically connect to the one or more AMC cards, the card connecter removably and replaceably connected to the first carrier cover and the second carrier cover. The card carrier may include an ejector positioned within a machined opening in the faceplate and positioned to permit user access from the front side of the faceplate. The card carrier may include a power connector affixed to the second carrier cover, the power connector providing an interconnect between an external power supply and one or more electronic components within the carrier. The card carrier may include a plurality of threaded inserts pressed into at least one of the first carrier cover and the second carrier cover. The card carrier may include a plurality of disposable standoffs removably positioned between the first carrier cover and the second carrier cover, the disposable standoffs maintaining a substantially fixed relationship between the first carrier cover and the second carrier cover.

### BRIEF DESCRIPTION OF THE FIGURES

The invention and the following detailed description of certain embodiments thereof may be understood by reference to the following figures:

FIG. 1 is an exploded view of an AMC carrier including a faceplate.

FIG. 2 is a side view of an extruded faceplate.

FIG. 3 is a front view of an extruded faceplate.

FIG. 4 is a rear view of an extruded faceplate.

FIG. 5 is a top view of an extruded faceplate.

FIG. 6 is a bottom view of an extruded faceplate.

### DETAILED DESCRIPTION

An extruded faceplate is described for use with AMC carriers. It while be understood that the carriers described herein may be referred to as AMC carriers in reference to the type of module carried, or as ATCA carriers in reference to the specification to which the carrier itself conforms. These carrier types are neither mutually exclusive nor mutually inclusive, and unless otherwise specified or clear from the context, general references to a carrier are intended to refer to either type of carrier or both. The principles of the invention may be suitably adapted to either type of carrier without departing from the scope and spirit of this disclosure.

It will be understood that the term chassis as used herein, refers to any ATCA chassis which may include a chassis having 2 slots, 5 slots, or 14 slots, as well as a chassis in a rack mount or a stand-alone form factor, and a chassis that receives carriers vertically or horizontally. A chassis may also or instead include any other chassis or hardware designed to receive a number of card carriers and connect them to an electrical system. A wide range of ATCA chassis and other chassis are readily commercially available.

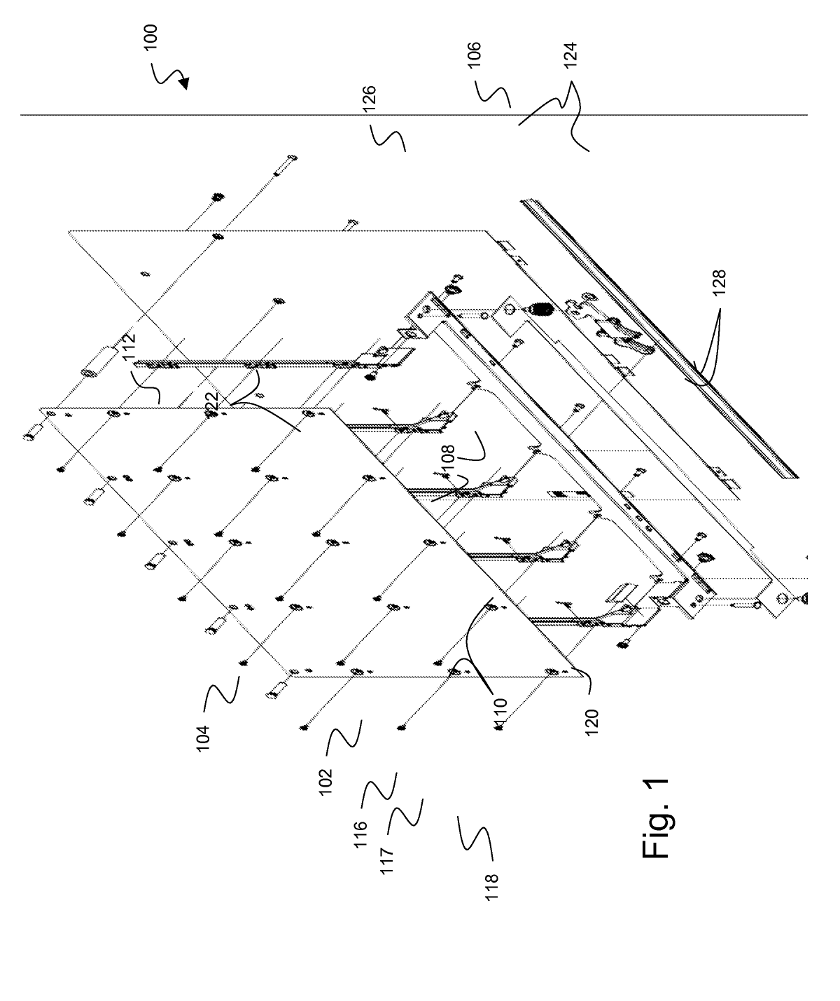

FIG. 1 is an exploded view of an AMC carrier including a faceplate. In general, a carrier 100 is formed from a faceplate 102, a top carrier cover 104, a bottom carrier cover 106, and a number of card guides 108 positioned to receive printed circuit boards and the like. A number of machine screws 110, threaded inserts 112, alignment pins, and the like may be used to secure the covers 104, 106, card guides 108, faceplate 102, and other components together into an assembled unit.

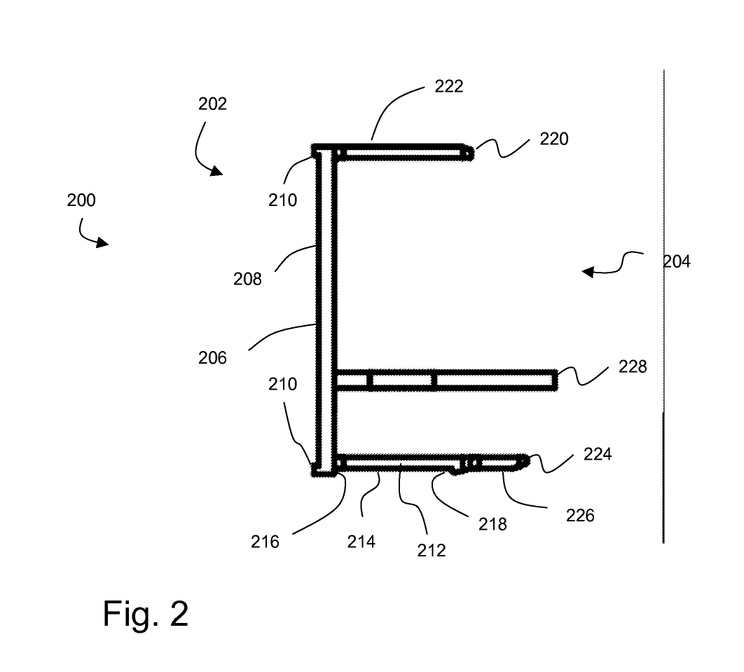

The faceplate 102 may be fashioned by extrusion of aluminum or any other suitable material or mixture of materials capable of extrusion. By way of example and not of limitation, suitable aluminum alloys include International Alloy Designation System numbers 6005-T6, 6061-T6, 6063-T5 and the like. Various features of the faceplate 102 are more specifically described below with reference to FIGS. 2-6. A number of specific components connected to the faceplate 102 are explained briefly here in the context of the entire carrier 100.

An adhesive overlay 116 may be affixed to the faceplate 102. The adhesive overlay 116 may have an adhesive back surface including any type of adhesive suitable for temporarily, permanently, or semi-permanently attaching the adhesive overlay 116 to the faceplate. A front surface of the adhesive overlay 116 may contain any desired visual information including company logos, graphics, product names or descriptions, indicator light labels, and so forth. The adhesive overlay 116 may be fabricated from any suitable plastic, rubber, metal film, or other material or combination of materials. The adhesive overlay 116 may include cutouts for through-holes such as for a captive screw 117 in the faceplate 102, notches on the edges or corners, such as for an ejector 118, and any number of translucent or transparent regions to permit light-emitting diodes (LEDs) or the like to emit light through the adhesive overlay 116.

One or more ejectors 118 may be provided that assist in removing or “ejecting” the carrier 100 from a chassis, more generally permitting user access to the carrier 100 from a front (or exterior) side of the faceplate 102, or more generally, from the front side of a chassis that houses the carrier 100. A number of types of ejectors suitable for use with a card carrier are known in the art and may be used with a carrier 100 as described herein. In standards-based carriers such as ATCA carriers, the faceplate 102 may include a standards-defined opening for the ejectors 118. The ejectors 118 may be positioned within a machined opening in the faceplate 102 as described in greater detail below.

An electromagnetic interference (“EMI”) gasket 120 or other grounded shielding or the like may be coupled to the faceplate 102, such as along a bottom edge thereof. The EMI gasket 120 may be an adhesive strip of EMI shield material having an adhesive backing for adhering to the faceplate 102 in an appropriate location. The EMI gasket may more generally be any suitable shielding material. In one embodiment, the EMI gasket 120 is formed of 4E06-AD-51K EMI shield gasket stripping commercially available from Laird Technologies.

The top carrier cover 104, also referred to in AdvancedTCA as the Carrier Side 1 or CS1 cover, may be removably and replaceably attached to a top edge of the faceplate 102 to form a top of the carrier 100. The top carrier cover 104 may include any number of holes 122 for mounting screws 112, threaded inserts 112, and so forth. Threaded inserts 112, for example, may be pressed into the inner surface or through the outer surface of either or both of the covers 104, 106 to align card guides 108 and the like during assembly of the carrier 100. A cover is typically although not necessarily fabricated from sheet metal of adequate thickness and strength for the intended use of the carrier 100.

The bottom carrier cover 106, also referred to in AdvancedTCA as the Carrier Side 2 or CS2 cover, may be removably and replaceably attached to a bottom edge of the faceplate 102 to form a bottom of the carrier 100. The bottom carrier cover 106 may include any number of holes 124 for mounting screws, and so forth. In general, holes may be pre-drilled in the bottom carrier cover 106 (and the top carrier cover 104) in predetermined locations according to a modular architecture for cards, card guides, and the like, or in application-specific locations for a power supply, disposable standoffs 126 (described below), or any other general or specific use. In order to more securely affix the bottom carrier cover 106 to the faceplate 102, offset fingers 128 may extend from the bottom carrier cover 106 in pairs (as shown), triplets, or other groupings. The offset fingers 128 may, for example, mate with a tapered edge (see FIG. 2) of the faceplate 102 such that the offset fingers 128 rest on either side of the tapered edge. In one embodiment, the cover may include six offset fingers 128 which alternate between a top and a bottom side of the tapered edge. The offset fingers 128 may be stamped into the sheet metal of the bottom carrier cover 106, or otherwise formed as an integral part of, or connected to, the cover. It will be understood that numerous variations to the number, position, and manufacture of offset fingers 128 are possible and are intended to fall within the scope of this description.

The card guides 108 may interconnect the top carrier cover 104 and the bottom carrier cover 106, with adjacent card guides 108 providing a pair of aligned rails for receiving and supporting a card or module such as an AMC card. In addition to aligning a card with a rear edge connector within the carrier 100, the card guides 108 may provide grounding, shielding, as well as mechanical features such as vibration damping or a locking mechanism to secure a card in a slot.

Although not depicted in FIG. 1, it will be understood that an assembled carrier 100 generally includes card connectors or the like for cards such as AMC cards that are inserted along the aligned rails of the card guides 108. The connectors, which may be edge connectors or the like, are generally aligned with the rails of the card guides 108 such that a card or circuit board inserted along the rails is physically and electronically connected with the carrier 100 and thus to any electronic system coupled to the carrier 100 through a backplane or the like. Each card connector may be removably and replaceably attached to the carrier covers 104, 108 using screws or the like. This mechanical connection, typically toward the rear of the carrier 100, also serves to strengthen the overall structure of the carrier 100 in combination with the faceplate 102 and other components. It will be understood that card carriers generally, and AMC or ATCA carriers in particular, may include additional components not shown in FIG. 1. For example, the carrier 100 may include a power connector affixed to one of the carrier covers 104, 108 to provide an interconnect between an external power supply and one or more electronic components within the carrier 100, or the carrier 100 may include a cooling or ventilation system suited to any electronics intended for use within the carrier 100.

In order to preserve the structural integrity of partially assembled carriers (e.g., carriers without card connectors or other components) during shipping and handling, disposable standoffs 126 made of nylon or any other suitable material may be secured between the carrier covers 104, 108 in various locations such as along a rear edge of the top carrier cover 104. In this position, the disposable standoffs 114 can maintain a substantially fixed physical relationship between the top carrier cover 104 and the bottom carrier cover 106.

FIG. 2 is a side view of an extruded faceplate. The faceplate 200, which may be for example the faceplate 102 described above with reference to FIG. 1, generally has a cross-sectional shape formed along its length during an extrusion process. Thus it will be understood that an extrusion shape or profile for the faceplate 200 is generally the same as the cross-sectional shape of the faceplate 200 but for any material changes during cooling or other artifacts of a particular extrusion process. Oriented relative to an AMC carrier (or any other carrier described above) of which it may form a part, the faceplate 200 has a front side 202 that forms an outside surface of the AMC carrier and a rear side 204 that forms an inside surface of the AMC carrier. The cross-sectional shape of the faceplate 200 may include a number of extruded features that provide structural and/or functional support to use in a card carrier.

The cross-sectional shape may include a channel 206 on the front side 202 of the faceplate 200 for confining an adhesive overlay (not shown) such as the adhesive overlay 116 described above in a desired location. The channel 206 may include a substantially planar surface 208 sized for the adhesive overlay. In this respect it will be understood that sized for an adhesive overlay means at least as wide from edge 210 to edge 212) as the overlay, and possibly wider than the overlay, with a length determined by the length at which the extrusion is cut rather than any feature of the cross-sectional shape. The channel 206 may include two raised edges 210, 212 that confine the adhesive overlay within the channel 206, which may assist in placement of the overlay and serve to retain the overlay in its position during regular use. In general, the adhesive overlay may be thinner than the channel so that its outer surface lies below the outermost portion of the raised edges 210, 212, or substantially equal to the thickness (i.e., depth) of the channel to provide a flush surface, or thicker than the overlay. By making the raised edges 210, 212 equal to or greater than the thickness of an adhesive overlay, the overlay can be advantageously protected from de-adhesion along its edges during use and handling of the faceplate 200.

The cross-sectional shape may also or instead include a channel 212 on a bottom surface of the faceplate 200, or between the front side 202 and the rear side 204, for confining an adhesive strip of EMI shield material (not shown) such as the EMI gasket 120 described above in a desired location. The channel 212 may be substantially perpendicular to the front side 202 and the rear side 204 as shown in FIG. 2. The channel 212 may include a substantially planar surface 214 sized for the adhesive strip of EMI shield material. In this respect it will be understood that sized for an adhesive strip means at least as wide (from edge 216 to edge 218) as the adhesive strip, and possibly wider than the adhesive strip, with a length determined by the length at which the extrusion is cut rather than any feature of the cross-sectional shape. The channel 212 may include two raised edges 216, 218 that confine the adhesive strip within the channel 212, which may assist in placement of the adhesive strip and serve to retain the adhesive strip in its position during regular use. In general although not exclusively, the adhesive strip is substantially thicker than the depth of the channel so that the shielding material can come into secure contact with an edge of a chassis or the like into which the carrier is inserted. More specifically, the channel 212 may be positioned to support the adhesive strip in a location where the faceplate 200 of an AMC carrier physically mates with the chassis. For a standards-based AMC carrier, this position is below the faceplate 200 and in front of a carrier cover connected to the bottom edge of the faceplate 200. In certain embodiments, the channel 214, or a similar channel in the same or a different location, may be positioned to support the adhesive strip in a location where the faceplate 200 physically contacts another faceplate in a carrier.

The cross-sectional shape may also or instead include a tapered edge 220 on a top side 222 of the faceplate 200. In general, the tapered edge 220 extends rearward from and substantially perpendicular to the rear surface 204, and facilitates insertion of the faceplate 200 (and an assembled carrier including the faceplate 200) into a chassis. The tapered edge 220 may be angled so that the edge does not present any substantial surfaces perpendicular to a direction of insertion of the carrier, thus generally serving to facilitate insertion of an AMC carrier or the like into a chassis by easing the carrier into position, and preventing any perimeter surface of the faceplate from catching on any substantially parallel surface on an edge of the chassis opening (or an adjacent faceplate within the chassis).

The cross-sectional shape may also or instead include a tapered edge 224 on a bottom side 226 of the faceplate 200. In general, the tapered edge 224 extends rearward from and substantially perpendicular to the rear surface 204, and facilitates insertion of the faceplate 200 (and an assembled carrier including the faceplate 200) into a chassis. The tapered edge 224 may be angled so that the edge does not present any substantial surfaces perpendicular to a direction of insertion of the carrier, thus generally serving to facilitate insertion of an AMC carrier or the like into a chassis by easing the carrier into position, and preventing any perimeter surface of the faceplate from catching on any substantially parallel surface on an edge of the chassis opening or an adjacent faceplate within the chassis. The tapered edge 224 may also or instead be shaped to facilitate attachment to a plurality of offset fingers extending from the bottom carrier cover as generally described above. It will be understood that while the tapered edges 220, 224 may be conveniently included within the cross-sectional shape of an extruded faceplate 200, these features may also, or instead, be readily machined into the faceplate 200 according to cost, convenience, or any other factors that might be considered in fabricating faceplates 200 as generally described herein.

The cross-sectional shape may also or instead include a card support 228 extending rearward from and substantially perpendicular to the rear surface 204 between the top side 222 and the bottom side 226 of the faceplate 200. The card support 228 may have a number of notches and/or other machined features to physically align and support card guides such as the card guides 108 described above within a carrier. The card support 228 is discussed in greater detail below.

Having described a number of extruded, cross-sectional features that generally support use of the faceplate with card carriers and improve on the features of a sheet metal faceplate, a number of machined features are now described in greater detail. These machined features are in general adapted for assembly of the faceplate into a substantially standards-compliant AMC carrier or the like.

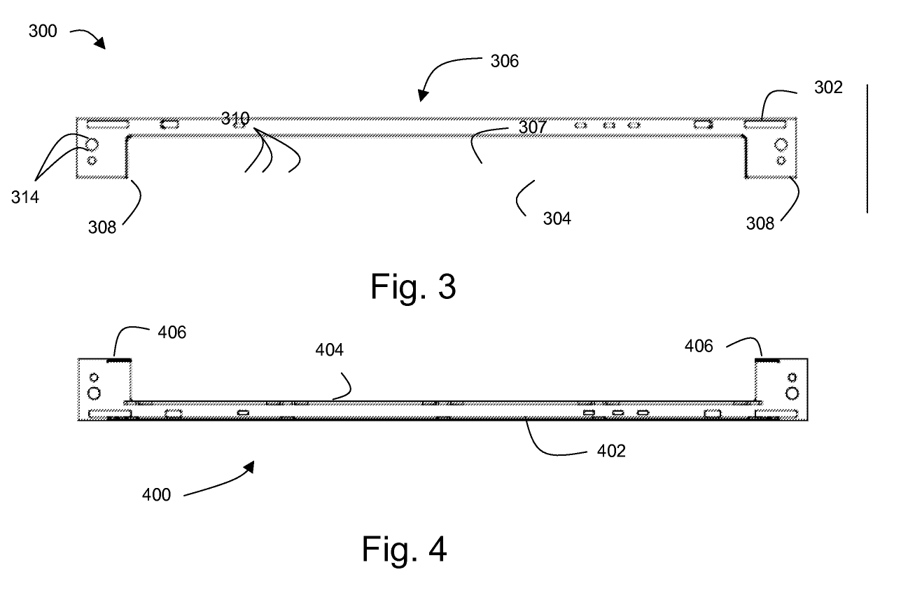

FIG. 3 is a front view of an extruded faceplate. The faceplate 300 has a length (from side to side horizontally in FIG. 3) sized for use as a faceplate in an AMC carrier. In a typical embodiment, a four card AMC carrier would use a 350 millimeter wide faceplate, or an extrusion 350 millimeters long. However it will be understood that shorter or longer faceplates may suitably be employed for various configurations and applications. As described above, a top edge 302 and a bottom edge 304 contain a raised edge to secure an adhesive overlay or the like along a front surface of the faceplate 300, it being understood that terms such as “top” and “bottom” are relative, and do not by themselves require any particular orientation of a card carrier or faceplate within a chassis or elsewhere. A number of machined features of the faceplate 300 are now described in greater detail. A wide range of machining, cutting, shaping, stamping, and hole cutting techniques are known in the art and may be suitably adapted to creating the machined features described herein.

An opening 306 may be machined into the faceplate 300 to receive individual cards or modules in a carrier constructed from the faceplate 300. For AMC carriers, the size and shape of this opening is largely defined by industry standards, as are many of the other features discussed below. The opening 306 may include a beveled edge 307 oriented to guide insertion of AMC modules into the opening 306 through the front surface of the faceplate 300.

One or more openings 308 may be provided to receive ejectors, such as any of the ejectors described above. Each opening 308 may extend through the faceplate 300 from a front side to a rear side of the faceplate 300 (as shown in FIG. 2 above) and may be shaped and sized to receive an ejector such that a mechanically operative portion of the ejector can extend through the faceplate 300 and cooperate with a chassis to releasably secure a carrier in the chassis. For hot-swappable components, the ejector may also disconnect or otherwise control power when releasing a carrier from the chassis, with a corresponding LED or the like indicating when the carrier is coupled to power within the chassis. Numerous suitable ejectors are commercially available for use with ATCA-compliant carriers and the like.

One or more through-holes 310 shaped and sized for light emitting diodes may be provided. The through-holes 310 may extend from the planar surface of the channel (front side) of the faceplate 300 to the rear side of the faceplate 300. In general, the position of these through-holes 310 may be specified by an industry standard or custom or proprietary specification, and transparent or translucent regions may be provided in complementary positions in an adhesive overlay so that LEDs positioned in the through-holes 310 are visible when illuminated.

One or more other through-holes 312 may also be provided that extend from a front side of the faceplate 300 to a rear side of the faceplate 300 for other components such as buttons, switches, dials and any other controls or human user interface components. In generally, each such through-hole 312 is shaped and sized for its intended component. Other through-holes 314 may be similarly provided for mechanical components such as captive screws, locating pins, carrier handles, and so forth.

FIG. 4 is a rear view of an extruded faceplate. The faceplate 400 may be any of the faceplates described above. When viewed from this perspective, a number of extruded features are visible. This includes for example a bottom edge 402, a card support 404, and a top edge 406.

The bottom edge 402 generally extends continuously along most of a bottom of the faceplate 400, and rearward from the interior of the faceplate 400. Although not visible from this perspective, the bottom edge 402 may include a number of extruded features described above such as a channel for an adhesive EMI gasket and a tapered edge for easing the faceplate and an associated card carrier into a chassis.

The card support 404 may extend rearward from and substantially perpendicular to the rear surface of the faceplate 400 as described above. The card support 404 is shown and described in greater detail below, but generally includes a number of notches machined into the surface thereof to support card guides in predetermined positions within a carrier.

The top edge 406 may extend rearward from and substantially perpendicular to the rear surface of the faceplate 400. In an embodiment, this extruded feature is mostly machined away when a card opening is formed in the faceplate. However, two regions of the top edge 406 may be retained as attachment legs for securing the faceplate 400 to a card guide strut, carrier cover, or the like.

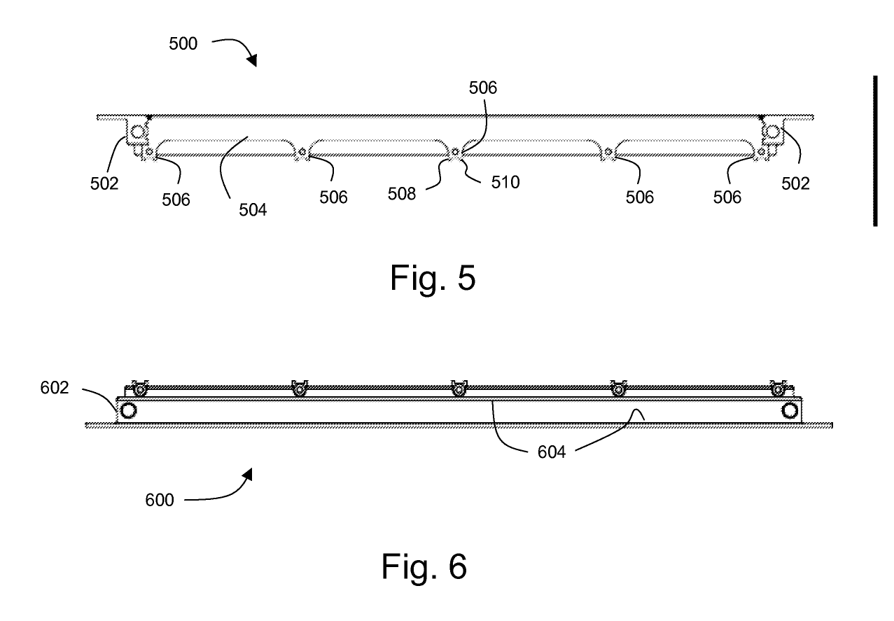

FIG. 5 is a top view of an extruded faceplate. The faceplate 500 may include any of the faceplates described above. From this top perspective, a number of features machined into extruded features of the faceplate 500 are visible, such as attachment legs 502 and a card support 504.

The attachment legs 502 may include one or more through-holes, and any other mechanical features suitable for attaching to, e.g., a card guide strut in a position that supports a carrier cover such as the top carrier cover described above. Although not visible from this perspective, it will be understood that the attachment legs 502 may include a tapered edge as generally described above for easing the faceplate 500 and an associated carrier into a chassis or the like.

The card support 504 may extend rearward and substantially perpendicular to a rear surface of the faceplate 500. While a perpendicular orientation may improve overall strength of the faceplate 500 and the card support 504, it will be appreciated that this orientation is not required by the extrusion process, and is not required for use in supporting card guides. Thus it will be understood that this orientation is illustrative only and, as with other such statements of orientation or geometry herein, provided by way of example and not of limitation. The card support 504 generally serves to physically position and stabilize a number of card guides within a carrier. For this purpose, a number of notches 506 may be formed by machining or the like in a rear edge of the card support. Each notch 506 may include two opposing lateral supports 508, 510 for a card guide that is positioned behind the faceplate 500. Each pair of lateral supports 508, 510 may serve to position and stabilize a card guide within a carrier constructed using the faceplate 500.

FIG. 6 is a bottom view of an extruded faceplate. The faceplate 600 may be, for example, any of the faceplates described above. From this perspective a bottom edge 602 of the faceplate 600 is visible. As described above, the bottom edge 602 generally extends continuously along most of a bottom of the faceplate 600, and rearward from the rear or interior surface of the faceplate 600. The bottom edge 602 may be tapered as described above, and may include a channel with raised edges 604 for an adhesive EMI gasket (not shown).

According to the foregoing, there is described an extruded aluminum faceplate that substantially conforms to the sheet-metal oriented AdvancedTCA specification, while providing numerous advantages impossible or impractical in a sheet metal fabrication process. It will be understood that some aspects of the AdvancedTCA specification are mandatory, while others are encouraged or optional. In certain instances, aspects of a faceplate and carrier may deviate somewhat from the requirements of the AdvancedTCA specification without departing from the scope of the invention. While the invention has been disclosed in connection with the preferred embodiments shown and described in detail, various modifications and improvements thereon will become readily apparent to those skilled in the art. Accordingly, the spirit and scope of the present invention is not to be limited by the foregoing examples, but is to be understood in the broadest sense allowable by law.

What is claimed is:

1. An extruded faceplate comprising:
an extruded material having a length sized for use as a faceplate for an AMC carrier, the extruded material having a front side that forms an outside surface of the AMC carrier and a rear side that forms an interior surface of the AMC carrier;
the extruded material having a cross-sectional shape including a channel on the front side, the channel including a depressed, substantially planar surface sized for an adhesive overlay and the channel including two raised edges that confine the adhesive overlay to the channel; and
the extruded material having at least one machined feature adapted for assembly into the AMC carrier.

2. The extruded faceplate of claim 1 wherein the channel has a depth substantially equal to a thickness of the adhesive overlay.

3. The extruded faceplate of claim 1 further comprising at least one through-hole from the planar surface of the channel to the rear side of the extruded faceplate, the at least one through-hole shaped and sized for a light emitting diode.

4. The extruded faceplate of claim 1 further comprising at least one through-hole from the planar surface of the channel to the rear side of the extruded faceplate, the at least one through-hole shaped and sized for at least one of a button, a switch, and a dial.

5. The extruded faceplate of claim 1 further comprising an opening from the front side to the rear side, the opening shaped and sized to receive an ejector.

6. The extruded faceplate of claim 1 further comprising the adhesive overlay adhered to the channel.

7. An extruded faceplate comprising:
an extruded material having a length sized for use as a faceplate for an AMC carrier, the extruded material having a front side that forms an outside surface of the AMC carrier and a rear side that forms an interior surface of the AMC carrier;
the extruded material having a cross-sectional shape including a channel between the front side and the rear side, the channel including a depressed, substantially planar surface sized for an adhesive strip of EMI shield material; and
the extruded material having at least one machined feature adapted for assembly into the AMC carrier.

8. The extruded faceplate of claim 7 wherein the channel is positioned to support the adhesive strip in a location where the AMC carrier physically mates with a chassis.

9. The extruded faceplate of claim 7 wherein the channel is positioned to support the adhesive strip in a location where the AMC carrier physically mates with another faceplate.

10. The extruded faceplate of claim 7 wherein the channel is substantially perpendicular to the front side and the rear side.

11. The extruded faceplate of claim 7 wherein the channel includes two raised edges that confine the adhesive strip to the channel.

12. The extruded faceplate of claim 7 further comprising the adhesive strip of EMI shield material adhered to the channel.

13. An extruded faceplate comprising:
an extruded material having a length sized for use as a faceplate for an AMC carrier, the extruded material having a front side that forms an outside surface of the AMC carrier and a rear side that forms an interior surface of the AMC carrier;
the extruded material having a cross-sectional shape including a tapered edge extending rearward from and substantially perpendicular to the rear surface; and
the extruded material having at least one machined feature adapted for assembly into the AMC carrier.

14. The extruded faceplate of claim 13 wherein the tapered edge includes at least one tapered side to facilitate insertion of the AMC carrier into a chassis.

15. The extruded faceplate of claim 13 wherein the tapered edge includes a taper to facilitate attachment to a plurality of offset fingers extending from a sheet metal carrier cover.

16. The extruded faceplate of claim 15 further comprising the sheet metal carrier cover, the sheet metal carrier cover attached to the extruded faceplate with at least two of the offset fingers on each side of the tapered edge.

17. An extruded faceplate comprising:
an extruded material having a length sized for use as a faceplate for an AMC carrier, the extruded material having a front side that forms an outside surface of the AMC carrier and a rear side that forms an interior surface of the AMC carrier;
the extruded material having a cross-sectional shape including at least one profile feature adapted for assembly into the AMC carrier; and
the extruded material having an opening machined therein extending from the front surface to the rear surface, the opening shaped and sized to receive an AMC module and the opening including a beveled edge oriented to guide insertion of the AMC module into the opening through the front surface.

18. The extruded faceplate of claim 17 further comprising at least one notch formed in an edge extending rearward from the rear surface, the notch providing two opposing lateral supports for a card guide positioned behind the extruded faceplate.

19. The extruded faceplate of claim 17 further comprising an attachment leg extruded into the cross-sectional shape and extending rearward from the rear surface, the attachment leg adapted to secure a card guide strut in a position to support a carrier cover.

20. A card carrier comprising:
a faceplate formed of an extruded material having a length sized for use in an AMC carrier, the faceplate having a front side that forms an outside surface of the AMC carrier and a rear side that forms an interior surface of the AMC carrier, the front side and the rear side connected by a top edge and a bottom edge to form a cross-sectional shape including at least one profile feature adapted for assembly into the AMC carrier, the extruded material further including at least one machined feature adapted for assembly into the AMC carrier, the faceplate forming a front of the card carrier;
a first carrier cover formed of sheet metal and removably and replaceably attached to the top edge of the faceplate, the first carrier cover forming a top of the card carrier;
a second carrier cover formed of sheet metal and removably and replaceably attached to the bottom edge of the faceplate, the second carrier cover forming a bottom of the card carrier; and
a plurality of card guides interconnecting the first carrier cover and the faceplate, wherein adjacent ones of the plurality of card guides provide a pair of aligned rails for receiving and supporting one or more AMC cards.

21. The card carrier of claim 20 further comprising at least one card connecter including an edge connecter aligned with the pair of aligned rails and adapted to physically and electronically connect to the one or more AMC cards, the card connecter removably and replaceably connected to the first carrier cover and the second carrier cover.

22. The card carrier of claim 20 further comprising an ejector positioned within a machined opening in the faceplate and positioned to permit user access from the front side of the faceplate.

23. The card carrier of claim 20 further comprising a power connector affixed to the second carrier cover, the power connector providing an interconnect between an external power supply and one or more electronic components within the carrier.

24. The card carrier of claim 20 further comprising a plurality of threaded inserts pressed into at least one of the first carrier cover and the second carrier cover.

25. The card carrier of claim 20 further comprising a plurality of disposable standoffs removably positioned between the first carrier cover and the second carrier cover, the disposable standoffs maintaining a substantially fixed relationship between the first carrier cover and the second carrier cover.
